(19) United States
(12) Patent Application Publication
(10) Pub. No.: US 2024/0304560 A1
(43) Pub. Date: Sep. 12, 2024

(54) SEMICONDUCTOR DEVICE AND METHOD OF MANUFACTURING THE SAME

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Kazuki KUWATA, Nisshin-shi (JP); Hiroshi ISHINO, Nisshin-shi (JP); Takeshi ENDO, Nisshin-shi (JP); Yoshitaka KATO, Nisshin-shi (JP)

(21) Appl. No.: 18/520,743

(22) Filed: Nov. 28, 2023

(30) Foreign Application Priority Data
Mar. 6, 2023 (JP) 2023-033929

(51) Int. Cl. H01L 23/538; H01L 21/56; H01L 21/60; H01L 23/00; H01L 23/31; H01L 25/16

(52) U.S. Cl. CPC H01L 23/5386; H01L 21/56; H01L 21/60; H01L 23/3121; H01L 24/81; H01L 24/95; H01L 25/16; H01L 24/16; H01L 24/32; H01L 24/73; H01L 2224/16245; H01L 2224/32225; H01L 2224/73253; H01L 2224/81191; H01L 2224/95; H01L 2924/10272; H01L 2924/13055; H01L 2924/13091; H01L 2924/1426

(57) ABSTRACT

A semiconductor device includes a first lead wire connected to a first connection target; a second lead wire connected to a second connection target; and a sealing resin that seals the first connection target, the second connection target, the first lead wire, and the second lead wire. The first lead wire includes a first connection portion connected to the first connection target, a first top portion exposed from the sealing resin, and a first standing portion connecting the first connection portion and the first top portion. The second lead wire includes a second connection portion connected to the second connection target, a second top portion exposed from the sealing resin, and a second standing portion connecting the second connection portion and the second top portion. The first top portion and the second top portion are disposed to face each other.

### CROSS REFERENCE TO RELATED APPLICATION

This application is based on Japanese Patent Application No. 2023-033929 filed on Mar. 6, 2023, the disclosure of which is incorporated herein by reference.

### TECHNICAL FIELD

The present disclosure relates to a semiconductor device and a method of manufacturing the semiconductor device.

### BACKGROUND

A semiconductor device includes a semiconductor element such as an insulated-gate bipolar transistor (IGBT) element that is sealed with a resin. An electrode of the semiconductor element is connected to a gate drive circuit via a bonding wire connected to the semiconductor element and a lead protruding from a side surface of a sealing resin.

### SUMMARY

According to an aspect of the present disclosure, a semiconductor device includes: a first connection target and a second connection target disposed on one surface of a substrate; a first lead wire connected to the first connection target; a second lead wire connected to the second connection target; and a sealing resin that seals the first connection target, the second connection target, the first lead wire, and the second lead wire. The first lead wire includes a first connection portion connected to the first connection target, a first top portion exposed from the sealing resin, and a first standing portion inclined with respect to the one surface and connecting the first connection portion and the first top portion. The second lead wire includes a second connection portion connected to the second connection target, a second top portion exposed from the sealing resin, and a second standing portion inclined with respect to the one surface and connecting the second connection portion and the second top portion. The first top portion and the second top portion are disposed to face each other.

### BRIEF DESCRIPTION OF DRAWING

FIG. 1 is a perspective view of a semiconductor device according to a first embodiment.

FIG. 2 is a perspective view illustrating an internal configuration of the semiconductor device.

FIG. 3 is a perspective view illustrating a semiconductor element.

FIG. 4 is a top view of the semiconductor element.

FIG. 5 is a cross-sectional view taken along line V-V in FIG. 4.

FIG. 6A is a sectional view illustrating a manufacturing process of the semiconductor device.

FIG. 6B is a sectional view illustrating a manufacturing process of the semiconductor device subsequent to FIG. 6A.

FIG. 6C is a sectional view illustrating a manufacturing process of the semiconductor device subsequent to FIG. 6B.

FIG. 6D is a sectional view illustrating a manufacturing process of the semiconductor device subsequent to FIG. 6C.

FIG. 6E is a sectional view illustrating a manufacturing process of the semiconductor device subsequent to FIG. 6D.

FIG. 7 is a perspective view illustrating a manufacturing process of the semiconductor device.

FIG. 8 is a cross-sectional view of a comparative example.

FIG. 9 is a sectional view illustrating a manufacturing process of a comparative example.

FIG. 10 is a top view of a semiconductor device according to a second embodiment.

FIG. 11 is a top view illustrating an internal configuration of the semiconductor device.

FIG. 12 is a top view illustrating a state in which plural wirings are arranged.

FIG. 13 is a top view illustrating a manufacturing process of the semiconductor device.

FIG. 14 is a perspective view illustrating a manufacturing process of a semiconductor device according to a third embodiment.

FIG. 15 is a top view illustrating a manufacturing process of the semiconductor device.

FIG. 16 is a cross-sectional view of a semiconductor device according to a fourth embodiment.

FIG. 17 is a cross-sectional view of a semiconductor device according to a fifth embodiment.

FIG. 18A is a sectional view illustrating a manufacturing process of the semiconductor device.

FIG. 18B is a sectional view illustrating a manufacturing process of the semiconductor device subsequent to FIG. 18A.

FIG. 19 is a cross-sectional view of a semiconductor device according to a sixth embodiment.

FIG. 20A is a sectional view illustrating a manufacturing process of the semiconductor device.

FIG. 20B is a sectional view illustrating a manufacturing process of the semiconductor device subsequent to FIG. 20A.

### DETAILED DESCRIPTION

Conventionally, a semiconductor device has a semiconductor element such as an IGBT (Insulated-Gate Bipolar Transistor) element which is sealed with a resin. An electrode of the semiconductor element is connected to a gate drive circuit via a bonding wire connected to the semiconductor element and a lead protruding from a side surface of a sealing resin. In such a connection method, since the wiring extends in the lateral direction, the dimension of the semiconductor device in the lateral direction increases. In addition, since the path length increases, the parasitic inductance increases.

For example, a wiring is formed to extend perpendicularly to an upper surface of a semiconductor element, and the semiconductor element and a drive circuit are connected by the wiring. In this case, it is possible to reduce the size of the semiconductor device without the wire bonding and to reduce the parasitic inductance due to the path shortening.

However, since it is difficult to hold the vertically drawn wiring alone, there is a concern that the wiring may collapse during resin sealing and a process failure may occur.

The present disclosure provides a semiconductor device and a method of manufacturing the semiconductor device so as to suppress the occurrence of defects.

According to a first aspect of the present disclosure, a semiconductor device includes: a first connection target and a second connection target disposed on one surface of a substrate; a first lead wire connected to the first connection target; a second lead wire connected to the second connection target; and a sealing resin that seals the first connection target, the second connection target, the first lead wire, and the second lead wire. The first lead wire includes a first connection portion connected to the first connection target, a first top portion exposed from the sealing resin, and a first standing portion inclined with respect to the one surface and connecting the first connection portion and the first top portion. The second lead wire includes a second connection portion connected to the second connection target, a second top portion exposed from the sealing resin, and a second standing portion inclined with respect to the one surface and connecting the second connection portion and the second top portion. The first top portion and the second top portion are disposed to face each other.

The first lead wire and the second lead wire can form a wiring having a shape that bridges the first connection target and the second connection target at the time of manufacturing the semiconductor device, while the first top portion and the second top portion are disposed to face each other. After resin sealing, a part of the wiring is removed. Since the wiring is supported at plural points by forming the wiring into a shape that bridges the plural connection targets, it is possible to suppress falling of the wiring due to resin sealing and to suppress occurrence of a defect.

According to another aspect of the present disclosure, a method of manufacturing a semiconductor device includes: disposing plural connection targets on one surface of a substrate; forming a bridge wiring having a shape that bridges the connection targets; sealing the connection targets and the bridge wiring with a sealing resin; exposing a part of the bridge wiring from a surface of the sealing resin; and dividing an exposed part of the bridge wiring.

Accordingly, since the wiring has a shape that bridges the connection targets and is supported at the plural points, it is possible to suppress the collapse of the wiring due to the resin sealing and to suppress the occurrence of a defect.

Embodiments of the present disclosure will be described hereinafter with reference to the drawings. In the following description, the same or equivalent parts are denoted by the same reference numerals throughout the embodiments.

### First Embodiment

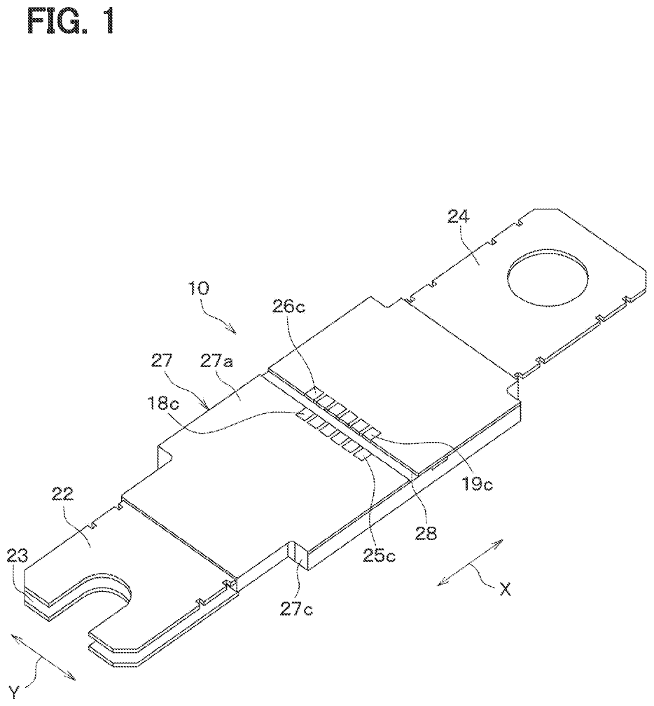

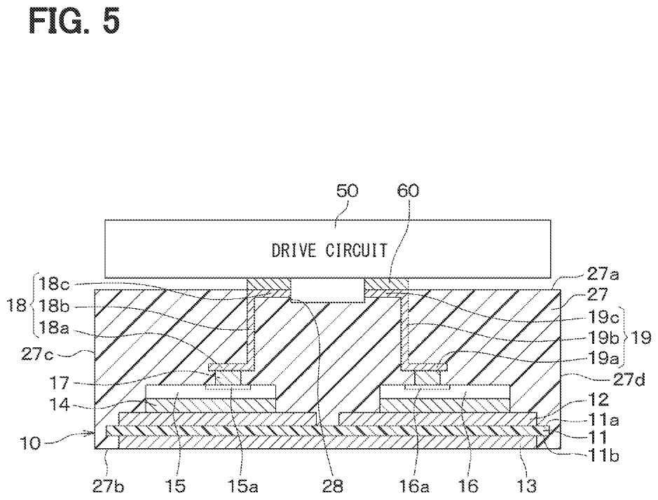

A first embodiment is described below. A semiconductor device 10 of the present embodiment illustrated in FIGS. 1 to 5 is a power module used as, for example, a switching device for driving a motor. As shown in FIGS. 1 to 5, the semiconductor device 10 includes a substrate 11, an upper surface wiring 12, a lower surface wiring 13, a bonding material 14, a semiconductor element 15, a semiconductor element 16, and a bonding material 17. The semiconductor device 10 includes a lead wire 18, a lead wire 19, a bus bar 20, a bus bar 21, a P terminal 22, an N terminal 23, an O terminal 24, a lead wire 25, a lead wire 26, and a sealing resin 27. As shown in FIG. 5, the semiconductor device 10 is connected to a drive circuit 50. The drive circuit 50 drives the semiconductor element 15, 16.

The substrate 11 is an insulating substrate made of resin or the like. The upper surface and the lower surface of the substrate 11 are referred to as one surface 11a and the other surface 11b, respectively. The upper surface wiring 12 and the lower surface wiring 13 are formed on the one surface 11a and the other surface 11b, respectively. The upper surface wiring 12 and the lower surface wiring 13 are made of a conductive metal such as copper or aluminum. The semiconductor element 15 and the semiconductor element 16 are bonded to the upper surface of the upper surface wiring 12 by a bonding material 14. The bonding material 14 is formed of solder or the like.

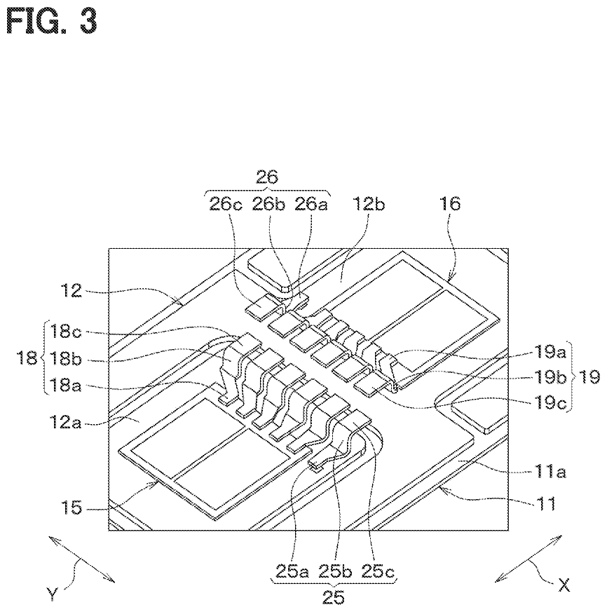

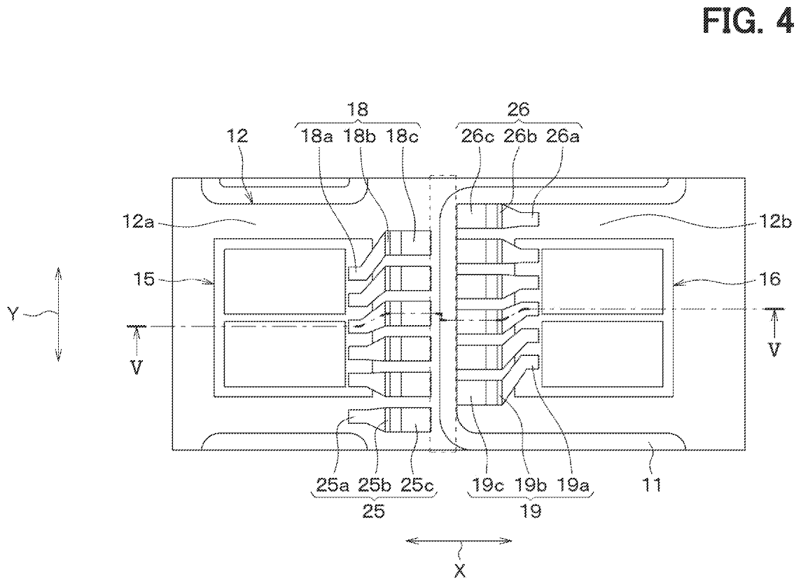

The semiconductor element 15, 16 is, for example, a switching element such as IGBT element or MOSFET (Metal-Oxide-Semiconductor Field-Effect Transistor) element using SiC (silicon carbide). The upper surface wiring 12 has an upper wiring 12a where the semiconductor element 15 is arranged, and an upper wiring 12b where the semiconductor element 16 is arranged. As shown in FIGS. 3 and 4, the upper wirings 12a and 12b are separated from each other. The semiconductor element 15 and the upper wiring 12a correspond to a first connection target. The semiconductor element 16 and the upper wiring 12b correspond to a second connection target.

As shown in FIG. 5, a signal pad 15a, 16a connected to the respective gate electrode is formed in the semiconductor element 15, 16. The signal pad 15a, 16a is one of a plurality of signal pads. The semiconductor element 15, 16 is connected to the lead wire 18, 19 by the bonding material 17 at the signal pad 15a, 16a. The bonding material 17 is formed of solder or the like. The lead wire 18, 19 connects the semiconductor element 15, 16 to the drive circuit 50, and is made of a conductive metal such as aluminum.

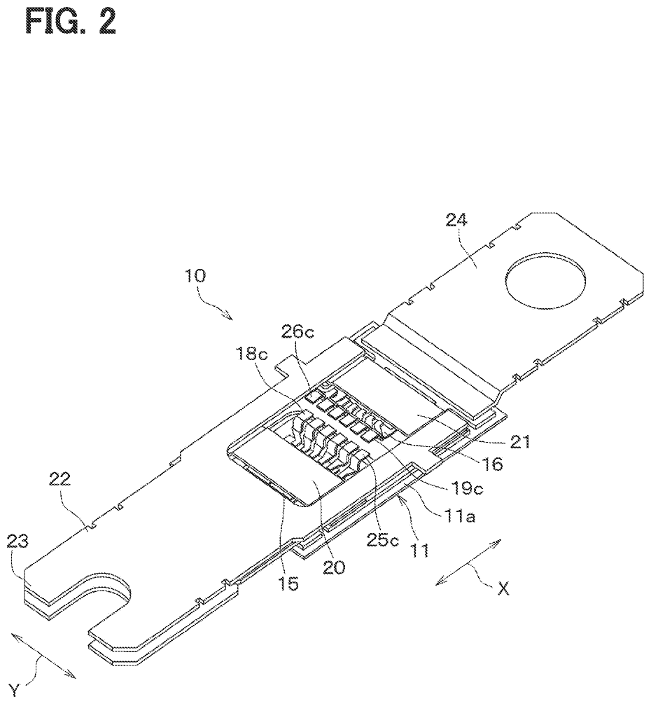

As shown in FIG. 2, the bus bar 20, 21 is bonded on the upper surface of the semiconductor element 15, 16. The semiconductor element 15, 16 is connected to the P terminal 22, the N terminal 23, and the O terminal 24 via the bus bar 20, 21 and the upper surface wiring 12. The P terminal 22, the N terminal 23, and the O terminal 24 connect the semiconductor element 15, 16 to a power supply (not shown), and are made of aluminum or the like.

The lead wire 25, 26 connects the upper wiring 12a, 12b to the drive circuit 50, and is made of a conductive metal such as aluminum. The lead wire 18, 25 corresponds to a first lead wire. The lead wire 19, 26 correspond to a second lead wire.

As shown in FIGS. 1 and 5, the substrate 11 to the lead wire 26 are sealed with the sealing resin 27. Two directions parallel to the one surface 11a and perpendicular to each other are defined as an X direction and a Y direction, respectively. The semiconductor elements 15 and 16 are arranged in the X direction. The sealing resin 27 is formed in a rectangular plate shape having the X direction as a longitudinal direction and the Y direction as a transverse direction. The upper surface of the sealing resin 27, that is the same side as the semiconductor element 15, 16 with respect to the substrate 11 is referred to as one surface 27a, and the lower surface opposite to the upper surface is referred to as the other surface 27b. The sealing resin 27 has two side surfaces 27c, 27d parallel to the Y direction.

A surface of the lower surface wiring 13 opposite to the substrate 11 is exposed from the other surface 27b. The end portions of the P terminal 22 and the N terminal 23 opposite to the upper surface wiring 12 and the semiconductor element 15, 16 protrude from the side surface 27c. The end portion of the O terminal 24 opposite to the upper surface wiring 12 and the semiconductor element 15, 16 protrudes from the side surface 27d. As shown in FIG. 1, a part of the sealing resin 27 protrudes from the side surface 27c and covers the roots of the P terminal 22 and the N terminal 23. A part of the sealing resin 27 protrudes from the side surface 27d and covers the root of the O terminal 24.

A part of the lead wire 18 is exposed from the sealing resin 27. Specifically, as shown in FIGS. 3 to 5, the lead wire 18 includes a connection portion 18a, a standing portion 18b, and a top portion 18c. The connection portion 18a is connected to the semiconductor element 15 and is formed in a plate shape parallel to the one surface 11a. The standing portion 18b connects the connection portion 18a and the top portion 18c. The standing portion 18b is inclined with respect to the one surface 11a, and stands on the side opposite to the substrate 11 with respect to the semiconductor element 15. The top portion 18c is connected to the drive circuit 50, and is formed in a plate shape parallel to the one surface 11a. The lead wire 18 is exposed from the one surface 27a on the upper surface of the top portion 18c. The top portion 18c is exposed to the inner peripheral portion of the one surface 27a separated from the side surfaces 27c and 27d and the other two side surfaces. The upper surface of the top portion 18c forms the same plane as the one surface 27a.

The same applies to the lead wires 19, 25, and 26. That is, the lead wire 19 includes a connection portion 19a, a standing portion 19b, and a top portion 19c. The connection portion 19a is connected to the semiconductor element 16. The standing portion 19b connects the connection portion 19a and the top portion 19c. The top portion 19c is connected to the drive circuit 50.

The lead wire 25 includes a connection portion 25a, a standing portion 25b, and a top portion 25c. The connection portion 25a is connected to the upper wiring 12a. The standing portion 25b connects the connection portion 25a and the top portion 25c. The top portion 25c is connected to the drive circuit 50.

The lead wire 26 includes a connection portion 26a, a standing portion 26b, and a top portion 26c. The connection portion 26a is connected to the upper wiring 12b. The standing portion 26b connects the connection portion 26a and the top portion 26c. The top portion 26c is connected to the drive circuit 50.

The connection portion 19a, 25a, 26a and the top portion 19c, 25c, 26c are formed in a plate shape parallel to the one surface 11a. The standing portion 19b, 25b, 26b is inclined with respect to the one surface 11a and stands on the side opposite to the substrate 11 with respect to the semiconductor element 16 and the upper wiring 12a, 12b. The lead wire 19, 25, 26 is exposed from the one surface 27a on the upper surface of the top portion 19c, 25c, 26c. The top portion 19c, 25c, 26c is exposed to the inner peripheral portion of the one surface 27a separated from the side surfaces 27c and 27d and the other two side surfaces. The upper surface of the top portion 19c, 25c, 26c forms the same plane as the one surface 27a.

In the present embodiment, the standing portion 18b, 19b, 25b, 26b is a plate-shaped member perpendicular to the one surface 11a. The connection portion 18a, 25a corresponds to a first connection portion. The standing portion 18b, 25b corresponds to a first standing portion. The top portion 18c, 25c corresponds to a first top portion. The connection portion 19a, 26a corresponds to a second connection portion. The standing portion 19b, 26b corresponds to a second standing portion. The top portion 19c, 26c corresponds to a second top portion.

As shown in FIGS. 1 and 5, a recess 28 is formed in the sealing resin 27. The recess 28 is opened in the one surface 27a and extends linearly in the Y direction. The recess 28 is formed between the top portion 18c, 25c and the top portion 19c, 26c. The top portion 18c, 25c and the top portion 19c, 26c face each other with the recess 28 interposed therebetween. The end face of the top portion 18c, 25c and the end face of the top portion 19c, 26c are exposed in the recess 28.

The lead wire 18 is one of a plurality of lead wires. The lead wire 19 is one of a plurality of lead wires. Specifically, five signal pads 15a, 16a are formed in the semiconductor element 15, 16. As shown in FIGS. 1 to 4, five lead wires 18, 19 are formed corresponding to the signal pads 15a, 16a, respectively. The five lead wires 18 and the lead wire 25 are arranged in the Y direction. The five lead wires 19 and the lead wire 26 are arranged in the Y direction, on the opposite side of the lead wire 18, 25 across the recess 28. A broken line area in FIG. 4 corresponds to the recess 28. The end faces of the five top portions 18c and the top portion 25c and the end faces of the five top portions 19c and the top portion 26c are exposed in the recess 28 and face each other with the recess 28 interposed therebetween.

Note that the top portion 18c, 25c may be located in front of the top portion 19c, 26c with the recess 28 interposed therebetween. As illustrated in FIGS. 1 to 4, the top portion 18c, 25c may be located at position shifted from the top portion 19c, 26c along the Y direction.

The semiconductor element 15, 16 is connected to a power supply (not illustrated) and an electric load such as a motor (not illustrated) via the P terminal 22, the N terminal 23, and the O terminal 24. As shown in FIG. 5, the semiconductor element 15, 16 is connected to the drive circuit 50 via the lead wire 18, 19 and the bonding material 60. In the semiconductor device 10, the semiconductor element 15, 16 is switched on and off by a signal input from the drive circuit 50 to the gate electrode of the semiconductor element 15, 16, and the supply current to the electric load is controlled.

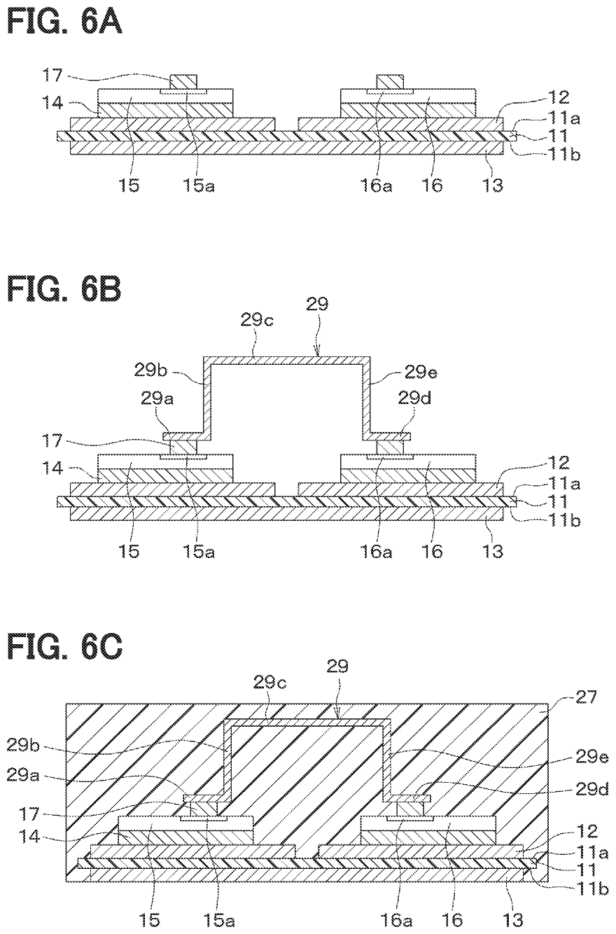

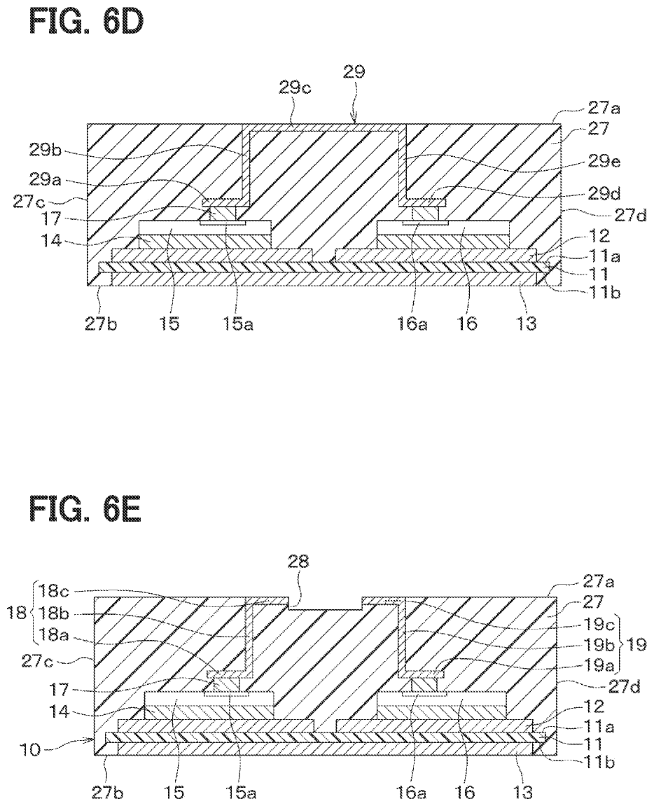

A method of manufacturing the semiconductor device 10 will be described. The semiconductor device 10 of the present embodiment is manufactured by steps shown in FIGS. 6A to 6E. In the step shown in FIG. 6A, the substrate 11 is prepared, and the upper surface wiring 12 is formed on the one surface 11a and the lower surface wiring 13 is formed on the other surface 11b by using photolithography and etching. In addition, the semiconductor element 15, 16 is formed by the semiconductor process, and bonded to the upper surface of the upper wiring 12a, 12b by the bonding material 14. Although not shown in FIGS. 6A to 6E, after the semiconductor element 15, 16 is bonded to the upper surface wiring 12, the bus bar 20, 21, the P terminal 22, the N terminal 23, and the O terminal 24 are bonded to the semiconductor element 15, 16 and the upper surface wiring 12.

In the step shown in FIG. 6B, wirings are connected to the semiconductor element 15, 16. Specifically, the bridge wiring 29 connecting the semiconductor element 15 and the semiconductor element 16 is prepared and bonded to the signal pad 15a, 16a formed on the upper surface of the semiconductor element 15, 16 by the bonding material 17. The bridge wiring 29 is also joined to the upper wiring 12a, 12b.

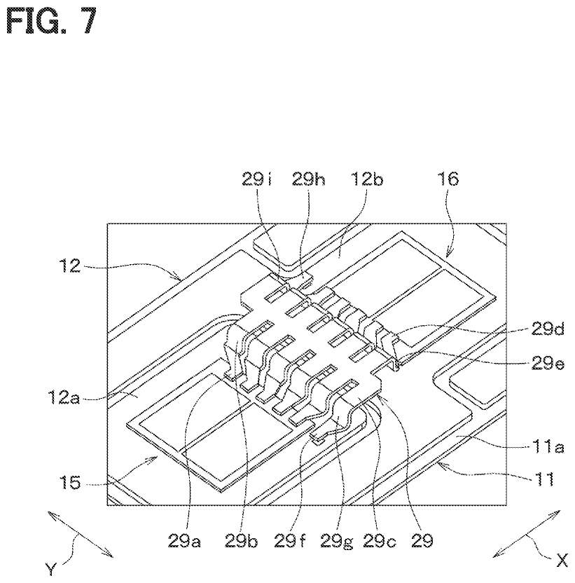

As shown in FIGS. 6B and 7, the bridge wiring 29 includes a connection portion 29a, a standing portion 29b, and a top portion 29c. The connection portion 29a is connected to the signal pad 15a, and is formed in a plate shape parallel to the one surface 11a. The standing portion 29b connects the connection portion 29a and the top portion 29c, and is inclined with respect to the one surface 11a. The standing portion 29b stands on the side opposite to the substrate 11 with respect to the semiconductor element 15. The top portion 29c is disposed on the side opposite to the semiconductor element 15 with respect to the connection portion 29a, and is formed in a plate shape parallel to the one surface 11a. The top portion 29c has a constant thickness.

The bridge wiring 29 includes a connection portion 29d connected to the signal pad 16a, and a standing portion 29e connecting the connection portion 29d and the top portion 29c. The bridge wiring 29 includes a connection portion 29f connected to the upper wiring 12a, and a standing portion 29g connecting the connection portion 29f and the top portion 29c. The bridge wiring 29 includes a connection portion 29h connected to the upper wiring 12b, and a standing portion 29i connecting the connection portion 29h and the top portion 29c. The connection portion 29d, 29f, 29h is formed in a plate shape parallel to the one surface 11a. The standing portion 29e, 29g, 29i is inclined with respect to the one surface 11a and stands on the side opposite to the substrate 11 with respect to the semiconductor element 16 and the upper wiring 12a, 12b. In the present embodiment, the standing portion 29b, 29e, 29g, 29i is a plate-shaped member perpendicular to the one surface 11a.

The bridge wiring 29 includes the plural connection portions 29a and 29d corresponding to the plural signal pads 15a and 16a. The plural standing portions 29b and 29e are formed corresponding to the connection portions 29a and 29d, and the plural standing portions 29b, 29e, 29g, 29i are connected to one top portion 29c. The top portion 29c includes a first part extending in the X direction and connected to the standing portion 29b, 29e, 29g, 29i, and a second part extending in the Y direction so as to connect the first parts connected to the standing portions 29b, 29e, 29g, 29i. As described above, five of the signal pads 15a, 16a are formed, and five of the connection portions 29a, 29d and five of the standing portions 29b, 29e are formed.

As described above, the bridge wiring 29 is shaped to bridge the semiconductor element 15 and the upper wiring 12a to the semiconductor element 16 and the upper wiring 12b. The bridge wiring 29 having such a shape is formed by, for example, press molding.

In the step shown in FIG. 6C, the substrate 11 to the bonding material 17 and the bridge wiring 29 are sealed with the sealing resin 27. The sealing resin 27 is formed so that a surface of the lower surface wiring 13 opposite to the substrate 11 and the end portions of the P terminal 22 to the O terminal 24 are exposed from the sealing resin 27.

In the step shown in FIG. 6D, a part of the sealing resin 27 is removed to expose the top portion 29c. Specifically, the surface layer portion of the sealing resin 27 located on the top portion 29c is removed by cutting. As a result, the upper surface of the top portion 29c is exposed from the sealing resin 27.

In the step shown in FIG. 6E, a part of the top portion 29c is removed to divide the bridge wiring 29, such that the lead wires 18, 19, 25, and 26 electrically insulated from each other are formed. Specifically, a part of the top portion 29c extending in the Y direction and a part of the sealing resin 27 thereunder are removed by cutting to form the recess 28 extending in the Y direction.

As a result, the bridge wiring 29 is divided into the lead wires 18, 19, 25, and 26. That is, the connection portion 29a, the standing portion 29b, and the top portion 29c partially connected to the standing portion 29b are defined as the connection portion 18a, the standing portion 18b, and the top portion 18c, respectively. The connection portion 29d, the standing portion 29e, and the top portion 29c partially connected to the standing portion 29e are defined as the connection portion 19a, the standing portion 19b, and the top portion 19c, respectively. The connection portion 29f, the standing portion 29g, and the top portion 29c partially connected to the standing portion 29g are defined as the connection portion 25a, the standing portion 25b, and the top portion 25c, respectively. The connection portion 29h, the standing portion 29i, and the top portion 29c partially connected to the standing portion 29i are defined as the connection portion 26a, the standing portion 26b, and the top portion 26c, respectively.

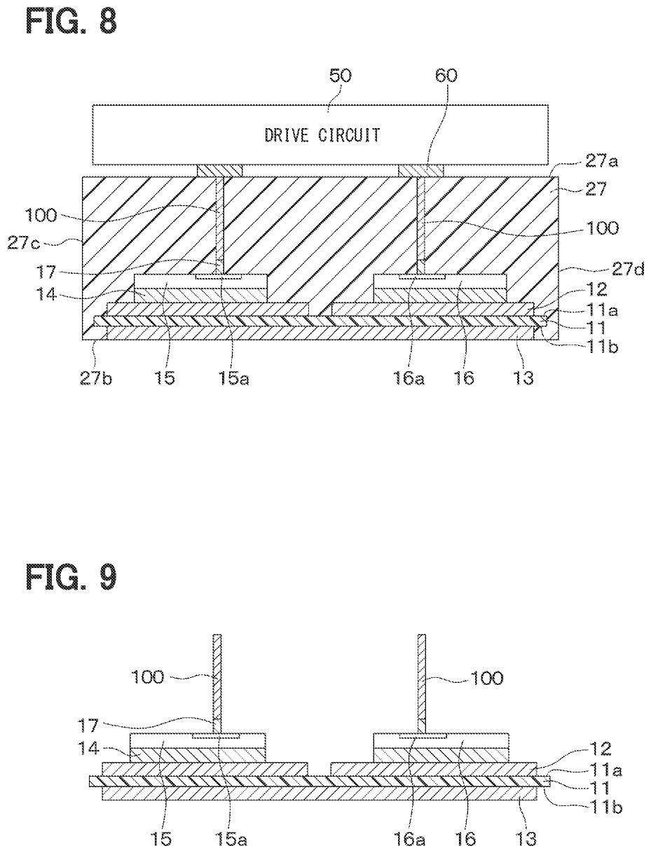

The effects of this embodiment are described. In a comparative example shown in FIG. 8, different from the semiconductor device 10 of the present embodiment, a vertical wiring 100 is provided instead of the lead wire 18, 19. The vertical wiring 100 is a rod-shaped wiring extending in a direction perpendicular to the one surface 11a, and has one end connected to the signal pad 15a, 16a via the bonding material 17. The other end is connected to the drive circuit 50 via the bonding material 60. In this comparative example, two vertical wirings (not shown) are provided instead of the lead wires 25 and 26. The two vertical wirings are rod-shaped wirings extending in a direction perpendicular to the one surface 11a, and one end of which is connected to the upper wiring 12a, 12b. The other end is connected to the drive circuit 50.

In the comparative example, after the process shown in FIG. 6A, the vertical wiring 100 is arranged, for example, as shown in FIG. 9. That is, each of the plural vertical wirings 100 is independently bonded to the semiconductor element 15, 16, and extends vertically to the one surface 11a.

When the substrate 11 and the like are resin-sealed in the same manner as in the process shown in FIG. 6C in a state where each of the vertical wirings 100 is individually held in this manner, the holding of the vertical wirings 100 is unstable. There is a concern that the vertical wirings 100 may collapse due to the inflow of the resin and a process failure may occur.

According to the present embodiment, the bridge wiring 29 to be the lead wire 18, 19, 25, 26 is disposed to bridge the upper wiring 12a, 12b and the semiconductor element 15, 16, and is supported at plural points by the connection portions 29a, 29d, 29f, 29h. Therefore, the bridge wiring 29 can be stably held, and is less likely to fall down during resin sealing.

As described above, in the present embodiment, the lead wires 18, 19, 25, and 26 are formed by disposing the bridge wiring 29 having a shape that bridges the plural connection targets and dividing the top portion 29c exposed from the sealing resin 27. Accordingly, since the bridge wiring 29 is supported at the plural points, it is possible to suppress the collapse of the bridge wiring 29 due to the resin sealing and to suppress the occurrence of the process failure.

### Second Embodiment

A second embodiment will be described. In the present embodiment, the configurations of the upper surface wiring 12 and the bridge wiring 29 are changed from those of the first embodiment, and the other configurations are the same as those of the first embodiment. Therefore, only portions different from those of the first embodiment will be described.

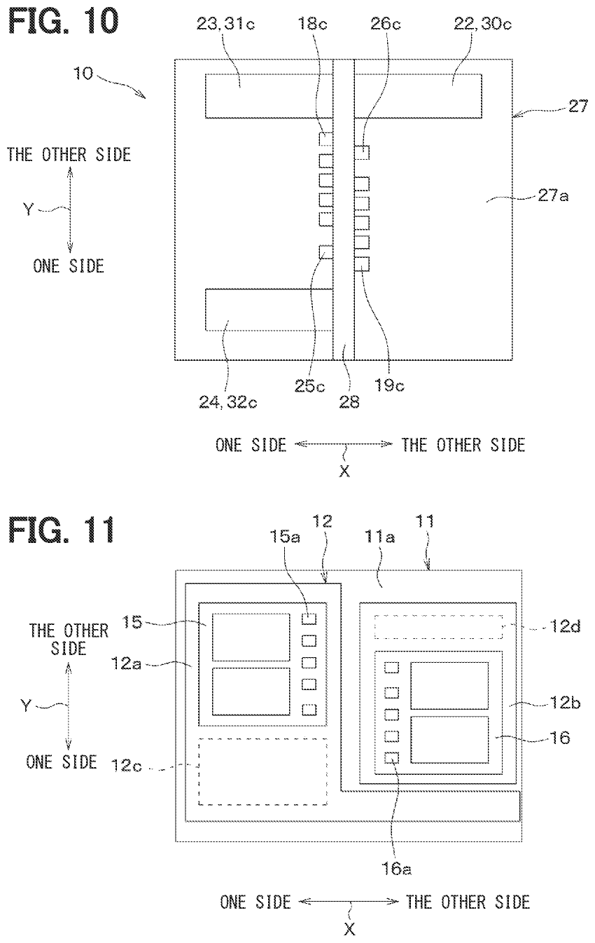

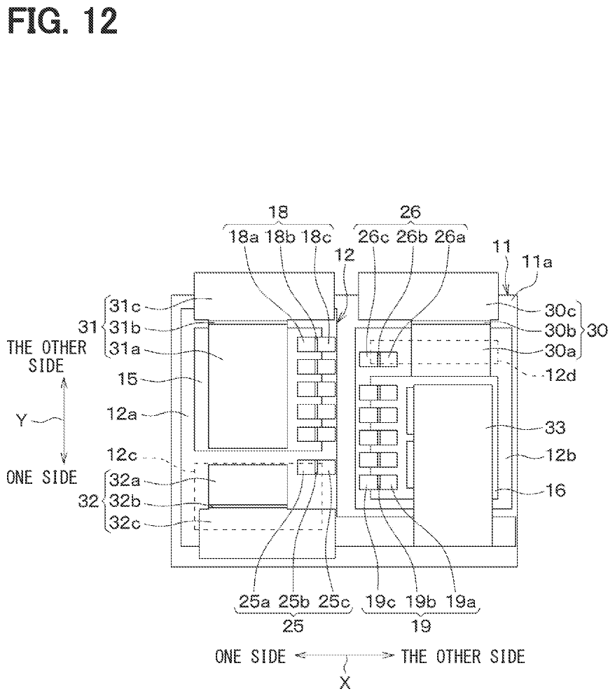

As shown in FIG. 10, the P terminal 22, the N terminal 23, and the O terminal 24 of the present embodiment are exposed from the one surface 27a of the sealing resin 27. As shown in FIG. 11, the upper wiring 12a, 12b has a large area secured outside the semiconductor element 15, 16. Specifically, a rectangular region 12c is secured on one side of the upper wiring 12a in the Y direction with respect to the semiconductor element 15. A rectangular region 12d is secured on the other side of the upper wiring 12b in the Y direction with respect to the semiconductor element 16. The lead wires 25 and 26 are connected to the regions 12c and 12d, respectively. As shown in FIG. 12, the semiconductor device 10 includes lead wires 30, 31, 32 and a bus bar 33.

The lead wire 30 connects the upper wiring 12b to the drive circuit 50. The lead wire 30 includes a connection portion 30a, a standing portion 30b, and a top portion 30c. The connection portion 30a is connected to the upper wiring 12b, and is joined to the region 12d. The standing portion 30b connects the connection portion 30a and the top portion 30c, and stands on the side opposite to the substrate 11 with respect to the upper wiring 12b so as to be inclined with respect to the one surface 11a. The top portion 30c is exposed from the one surface 27a and is connected to the drive circuit 50. The P terminal 22 includes the top portion 30c.

The lead wire 31 connects an electrode formed on the upper surface of the semiconductor element 15 to the drive circuit 50. The lead wire 31 includes a connection portion 31a, a standing portion 31b, and a top portion 31c. The connection portion 31a is connected to the upper surface electrode of the semiconductor element 15. The standing portion 31b connects the connection portion 31a and the top portion 31c, and stands on the side opposite to the substrate 11 with respect to the semiconductor element 15 so as to be inclined with respect to the one surface 11a. The top portion 31c is exposed from the one surface 27a and is connected to the drive circuit 50. The N terminal 23 includes the top portion 31c.

The lead wire 32 connects the upper wiring 12a to the drive circuit 50. The lead wire 32 includes a connection portion 32a, a standing portion 32b, and a top portion 32c. The connection portion 32a is connected to the upper wiring 12a, and is joined to the region 12c. The standing portion 32b connects the connection portion 32a and the top portion 32c, and stands on the side opposite to the substrate 11 with respect to the upper wiring 12a so as to be inclined with respect to the one surface 11a. The top portion 32c is exposed from the one surface 27a and is connected to the drive circuit 50. The O terminal 24 includes the top portion 32c.

The connection portion 30a, 31a, 32a and the top portion 30c, 31c, 32c are plate-like members parallel to the one surface 11a. The standing portion 30b, 31b, 32b is a plate-shaped member perpendicular to the one surface 11a.

The bus bar 33 is bonded to the upper surface of the semiconductor element 16. The semiconductor element 15, 16 is connected to the drive circuit 50 via the upper surface wiring 12, the lead wire 30, 31, 32, and the bus bar 33.

As shown in FIG. 10, the top portions 18c, 25c, 31c, 32c are arranged in the order of the top portions 32c, 25c, 18c, and 31c in the Y direction. The top portions 19c, 26c, 30c are arranged in the order of the top portions 19c, 26c, and 30c in the Y direction. The top portion 18c, 25c, 31c, 32c and the top portion 19c, 26c, 30c face each other with the recess 28 interposed therebetween. The tip surface of the top portion 18c, 25c, 31c, 32c and the tip surface of the top portion 19c, 26c, 30c are exposed in the recess 28.

In the present embodiment, the lead wire 18, 25, 31, 32 corresponds to a first lead wire, and the lead wire 19, 26, 30 corresponds to a second lead wire. The connection portion 31a, 32a corresponds to a first connection portion, the standing portion 31b, 32b corresponds to a first standing portion, and the top portion 31c, 32c corresponds to a first top portion. The connection portion 30a corresponds to a second connection portion, the standing portion 30b corresponds to a second standing portion, and the top portion 30c corresponds to a second top portion.

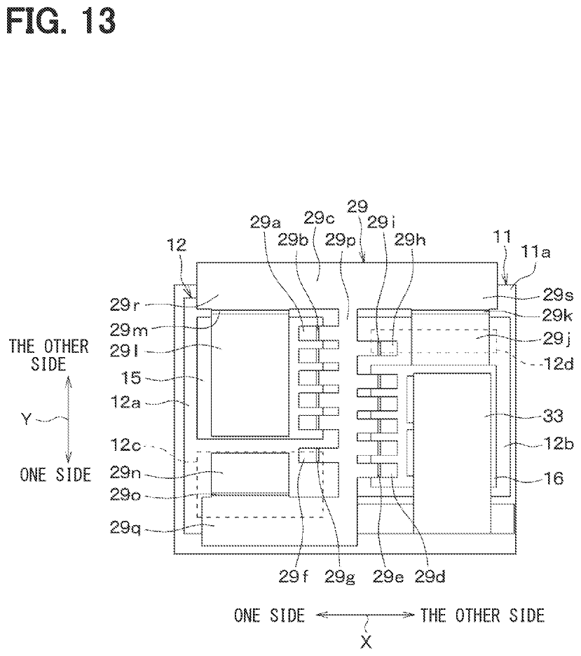

In the present embodiment, after the process shown in FIG. 6A, the bridge wiring 29 and the bus bar 33 having the shape shown in FIG. 13 are arranged. The bridge wiring 29 of the present embodiment is shaped to bridge the signal pad 15a of the semiconductor element 15, the upper surface electrode of the semiconductor element 15, the region 12c, the signal pad 16a of the semiconductor element 16, and the region 12d. The bridge wiring 29 includes a connection portion 29j, a standing portion 29k, a connection portion 29l, a standing portion 29m, a connection portion 29n, a standing portion 29o in addition to the connection portion 29a to the standing portion 29i.

The connection portion 29j is connected to the region 12d. The standing portion 29k connects the connection portion 29j and the top portion 29c. The connection portion 29l is connected to the upper surface electrode of the semiconductor element 15. The standing portion 29m connects the connection portion 29l and the top portion 29c. The connection portion 29n is connected to the region 12c. The standing portion 29o connects the connection portion 29n and the top portion 29c.

The connection portion 29j, 29l, 29n is formed in a plate shape parallel to the one surface 11a. The standing portion 29k, 29m, 29o is inclined with respect to the one surface 11a and stands on the side opposite to the substrate 11 with respect to the upper surface wiring 12 and the semiconductor element 15. In the present embodiment, the standing portion 29k, 29m, 29o is a plate-shaped member perpendicular to the one surface 11a.

The top portion 29c includes a part extending in the Y direction. This extended portion is referred to as a top portion 29p. The top portion 29c extends to one side in the X direction at one end of the top portion 29p in the Y direction. This extended portion is referred to as a top portion 29q. The top portion 29c extends to one side in the X direction and the other side in the X direction at the other end in the Y direction of the top portion 29p. A portion extending to one side in the X direction is referred to as a top portion 29r, and a portion extending to the other side in the X direction is referred to as a top portion 29s.

The standing portion 29b, 29g is connected to one side of the top portion 29p in the X direction. The standing portion 29e, 29i is connected to the other side of the top portion 29p in the X direction. The standing portion 29k is connected to one side of the top portion 29s in the Y direction. The standing portion 29m is connected to one side of the top portion 29r in the Y direction. The standing portion 29o is connected to the other side of the top portion 29q in the Y direction.

In the present embodiment, the substrate 11 and the like are sealed with the sealing resin 27, and the top portion 29c is exposed by cutting the sealing resin 27. Then, the top portion 29p is removed by cutting to form the recess 28. As a result, the bridge wiring 29 is divided, and the lead wires 18, 19, 25, 26, 30, 31, and 32 are formed.

That is, as in the first embodiment, a part of the connection portion 29a, 29d, 29f, 29h, the standing portion 29b, 29e, 29g, 29i, and the top portion 29c becomes the lead wire 18, 19, 25, 26. The connection portion 29j, the standing portion 29k, and the top portion 29s are the connection portion 30a, the standing portion 30b, and the top portion 30c, respectively. In addition, the connection portion 29l, the standing portion 29m, and the top portion 29r are the connection portion 31a, the standing portion 31b, and the top portion 31c, respectively. The connection portion 29n, the standing portion 29o, and the top portion 29q are the connection portion 32a, the standing portion 32b, and the top portion 32c, respectively.

In the present embodiment, since a part of the power wiring having a large bonding area is configured by the bridge wiring 29, it is possible to more stably hold the bridge wiring 29. It is possible to further suppress the collapse of the bridge wiring 29 due to resin sealing.

In the present embodiment, it is possible to attain the advantageous effects as similar to the effects in the first embodiment with the configuration and operation identical to the ones in the first embodiment.

### Third Embodiment

A third embodiment will be described. The present embodiment is the same as the first embodiment except that the configuration of the bridge wiring 29 is changed from that of the first embodiment. Therefore, only a portion different from the first embodiment will be described.

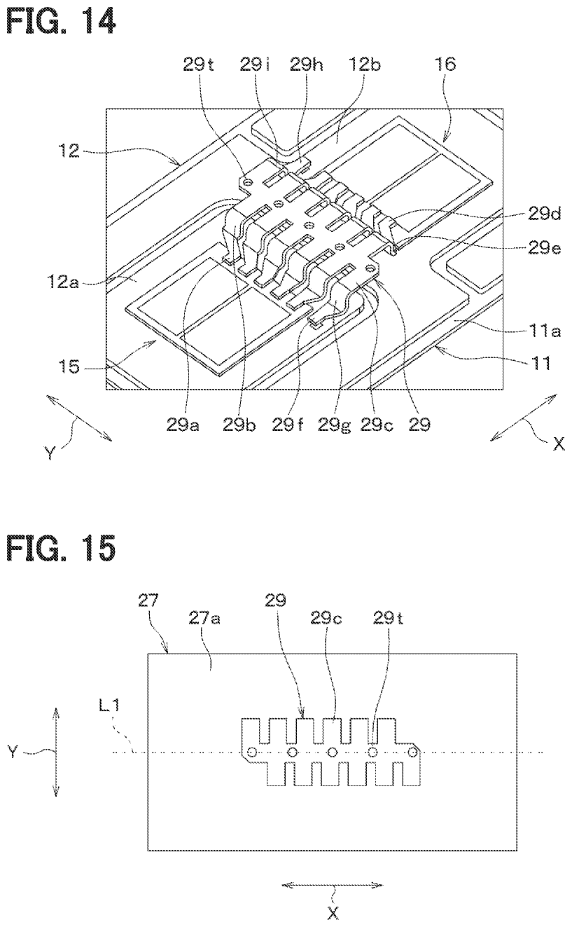

In the present embodiment, in the step shown in FIG. 6B, the bridge wiring 29 shown in FIG. 14 is arranged. A hole 29t penetrating through the top portion 29c is formed in the bridge wiring 29. Plural holes 29t are formed and arranged in the Y direction. In FIG. 14, the hole 29t is opened in a circular shape on the upper surface of the top portion 29c, but the hole 29t may be opened in another shape, for example, a rectangular shape. The hole 29t is formed, for example, when the bridge wiring 29 is press-formed.

In the step shown in FIG. 6E, the cutting is performed by positioning the cutting tool with reference to the hole 29t. Specifically, as shown in FIG. 15, the straight line L1 connecting the plural holes 29t is set to be along the central axis of the movement path of the cutting tool, and cutting is performed.

In the present embodiment, it is possible to attain the advantageous effects as similar to the effects in the first embodiment with the configuration and operation identical to the ones in the first embodiment.

According to the above embodiment, it is possible to achieve the following advantageous effects.

(1) The hole 29t is formed in a portion of the bridge wiring 29 exposed from the sealing resin 27 in the step shown in FIG. 6D, and a portion of the bridge wiring 29 in which the hole 29t is formed is removed in the step shown in FIG. 6E. According to this, since the central axis of the region where the recess 28 is formed is easily visible, it is possible to suppress the positional deviation of the recess 28. In addition, since the removed portion occupied by the top portion 29c is reduced and the removed portion occupied by the sealing resin 27 is increased, at the time of forming the recess 28, the cutting stress on the bridge wiring 29 is reduced. Thus, the peeling of the bridge wiring 29 from the sealing resin 27 can be suppressed, and the insulating property can be improved.

### Fourth Embodiment

A fourth embodiment will be described. The present embodiment is the same as the first embodiment except that an embedded resin is added to the first embodiment. Therefore, only a portion different from the first embodiment will be described.

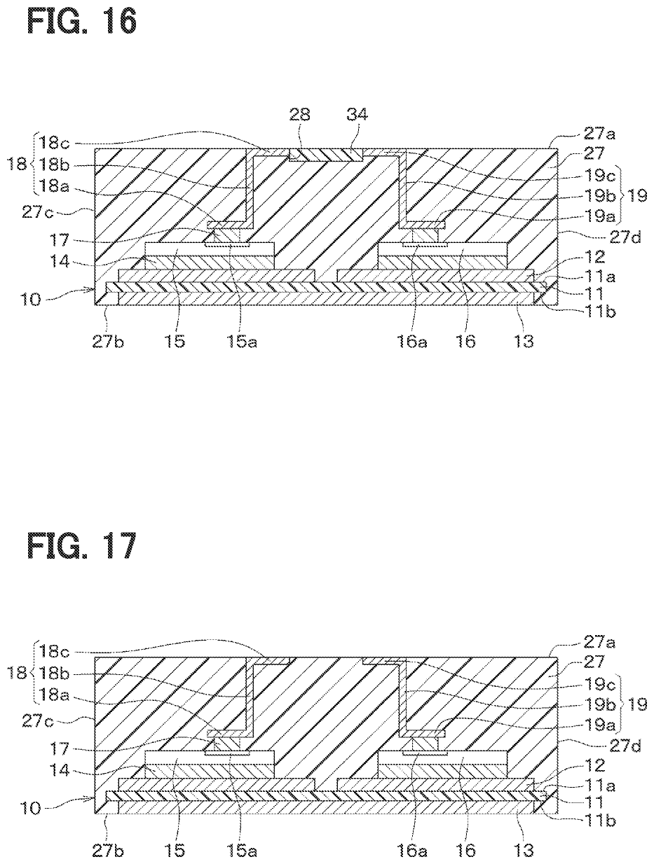

As shown in FIG. 16, the semiconductor device 10 of the present embodiment includes the embedded resin 34 that embeds the recess 28. The tip surface of the top portion 18c and the tip surface of the top portion 19c face each other with the embedded resin 34 interposed therebetween. The embedded resin 34 is made of an insulating resin material. In addition, the embedded resin 34 is a resin having a smaller filler than the sealing resin 27, which is suitable for filling the gap.

The embedded resin 34 is embedded in the recess 28 by, for example, application after the process shown in FIG. 6E and before the drive circuit 50 is bonded to the semiconductor device 10.

In the present embodiment, it is possible to achieve the advantageous effects as similar to the effects in the first embodiment with the configuration and operation identical to the ones in the first embodiment.

Further, according to the embodiment, it is possible to achieve the following advantageous effects.

(1) The embedded resin 34 is provided to embed the recess 28. According to this, since the tip of the top portion 18c, 19c is covered with the resin, the insulation property is improved.

### Fifth Embodiment

A fifth embodiment will be described. In the present embodiment, the configurations of the sealing resin 27 and the bridge wiring 29 are changed from those of the first embodiment, and the other configurations are the same as those of the first embodiment. Therefore, only portions different from those of the first embodiment will be described.

As shown in FIG. 17, the recess 28 is not formed in the sealing resin 27 of the present embodiment, and the one surface 27a is a flat surface. The top portion 18c and the top portion 19c face each other with a part of the sealing resin 27 interposed therebetween.

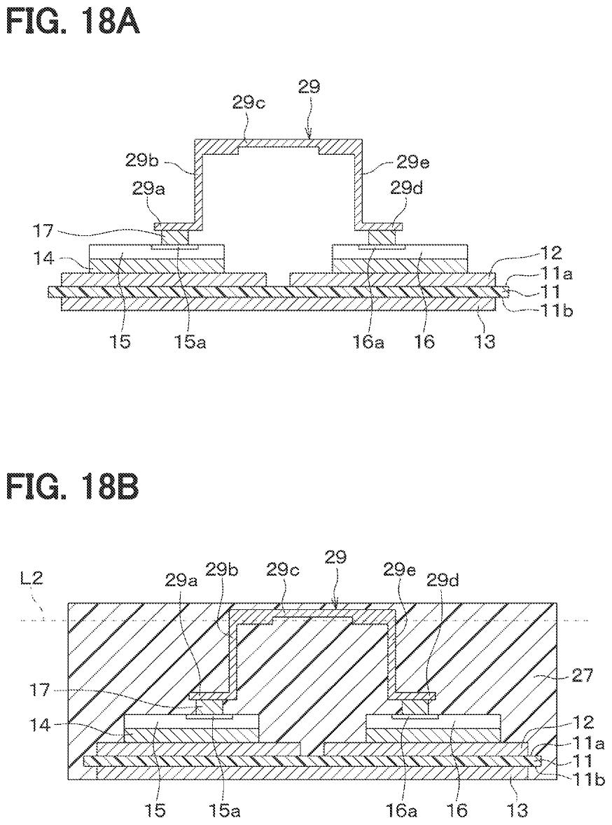

In the present embodiment, after the process shown in FIG. 6A, the bridge wiring 29 having the shape shown in FIG. 18A is arranged. In the bridge wiring 29, a recess is formed on the lower side of the top portion 29c. The recess is formed in a straight line parallel to the Y direction so as to extend from one end of the top portion 29c in the Y direction to the other end. Accordingly, the thickness of the central portion of the top portion 29c is smaller than the thickness of the portions connected to the standing portion 29b, 29e, 29g, 29i.

In the step shown in FIG. 18B, after the substrate 11 and the like are sealed with resin, the sealing resin 27 and the bridge wiring 29 are cut at the position of the broken line L2. As a result, the central part of the top portion 29c having a reduced thickness is removed, and the bridge wiring 29 is divided, so that the lead wire 18, 19, 25, 26 is formed.

In the step shown in FIG. 18B, at least a part of the top portion 29c below the broken line L2 may be sealed by the sealing resin 27, and a part of the bridge wiring 29 above the broken line L2 may be exposed from the sealing resin 27.

In the present embodiment, it is possible to achieve the advantageous effects as similar to the effects in the first embodiment with the configuration and operation identical to the ones in the first embodiment.

### Sixth Embodiment

A sixth embodiment will be described. The present embodiment is the same as the fifth embodiment except that the shape of the bridge wiring 29 is changed from that of the fifth embodiment. Therefore, only the portions different from the fifth embodiment will be described.

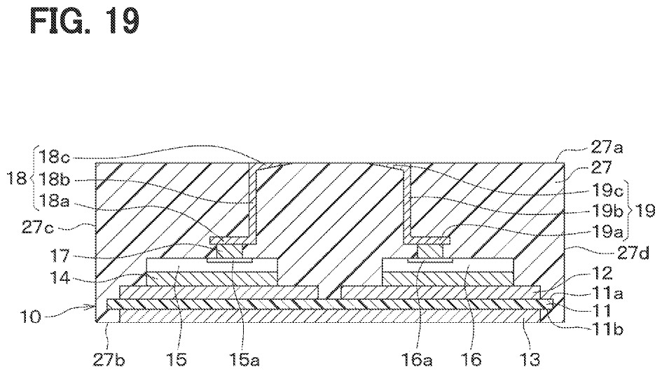

As shown in FIG. 19, the top portion 18c of the present embodiment has a tapered shape in which the thickness decreases from a part connected to the standing portion 18b toward the tip end facing the top portion 19c. The top portion 19c has a tapered shape in which the thickness decreases from a part connected to the standing portion 19b toward the tip end facing the top portion 18c.

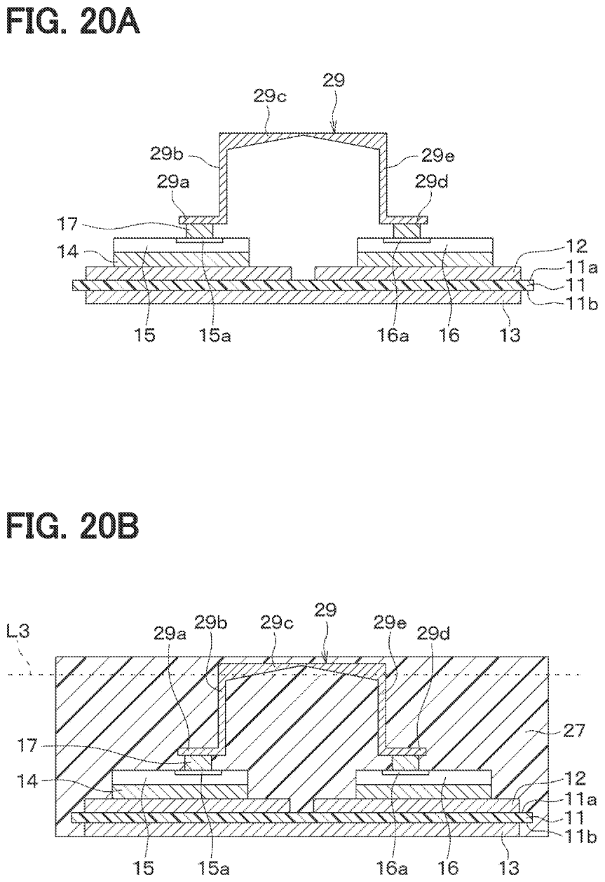

In the present embodiment, after the process shown in FIG. 6A, the bridge wiring 29 having the shape shown in FIG. 20A is arranged. In the bridge wiring 29, a recess is formed on the lower side of the top portion 29c. The recess is formed in a straight line parallel to the Y direction so as to extend from one end of the top portion 29c in the Y direction to the other end. In addition, the recess is formed such that the depth thereof increases from the one end in the X direction and the other end in the X direction of the top portion 29c toward the central portion. As a result, the thickness of the top portion 29c decreases from the part connected to the standing portion 29b, 29e, 29g, 29i toward the central portion.

In the step shown in FIG. 20B, after the substrate 11 and the like are sealed with resin, the sealing resin 27 and the bridge wiring 29 are cut at the position of the broken line L3. As a result, the central portion of the top portion 29c having a thickness smaller than a predetermined value is removed so as to divide the bridge wiring 29, such that the lead wires 18, 19, 25, and 26 are formed.

In the step shown in FIG. 20B, at least a part of the top portion 29c below the broken line L3 may be sealed by the sealing resin 27, and a part of the bridge wiring 29 above the broken line L3 may be exposed from the sealing resin 27.

In the present embodiment, it is possible to achieve the advantageous effects as similar to the effects in the first and fifth embodiments with the configuration and operation identical to the ones in the first and fifth embodiments.

### Other Embodiments

The present disclosure is not limited to the embodiments described above, and can be appropriately modified within the scope described in the claims. Individual elements or features of a particular embodiment are generally not limited to that particular embodiment, but, where applicable, are interchangeable and can be used in a selected embodiment, even if not specifically shown or described. Further, in each of the above-mentioned embodiments, it goes without saying that components of the embodiment are not necessarily essential except for a case in which the components are particularly clearly specified as essential components, a case in which the components are clearly considered in principle as essential components, and the like. Further, in each of the embodiments described above, when numerical values such as the number, numerical value, quantity, range, and the like of the constituent elements of the embodiment are referred to, except in the case where the numerical values are expressly indispensable in particular, the case where the numerical values are obviously limited to a specific number in principle, and the like, the present disclosure is not limited to the specific number. Further, in each of the embodiments described above, when referring to the shape, positional relationship, and the like of the components and the like, it is not limited to the shape, positional relationship, and the like, except for the case where the components are specifically specified, the case where the components are fundamentally limited to a specific shape, positional relationship, and the like.

In the second embodiment, the hole 29t may be formed as in the third embodiment. In the second and third embodiments, the recess 28 may be filled with the embedded resin 34 as in the fourth embodiment. In the second to fourth embodiments, a part of the top portion 29c may be thinned as in the fifth and sixth embodiments. In the fifth and sixth embodiments, the bridge wiring 29 may be divided by forming the recess 28 as in the first embodiment.

In each of the embodiments, the semiconductor element 15 and the upper wiring 12a are set as the first connection target, and the semiconductor element 16 and the upper wiring 12b are set as the second connection target. However, only the semiconductor element 15 may be set as the first connection target, or only the upper wiring 12a may be set as the first connection target. Only the semiconductor element 16 may be the second connection target, or only the upper wiring 12b may be the second connection target. The first and second connection targets may include members other than the semiconductor element 15, 16 and the upper surface wiring 12. For example, the substrate 11 may be included in one or both of the first and second connection targets.

The bridge wiring 29 may be supported at least two points. That is, the semiconductor device 10 may include at least one first lead wire and at least one second lead wire. However, by supporting the bridge wiring 29 at three points, it is possible to more stably hold the bridge wiring 29, and it is possible to further suppress the collapse of the bridge wiring 29 due to resin sealing. In this case, two or more of at least one of the first lead wire and the second lead wire are formed.

The standing portion 18b, the standing portion 19b, and the standing portion 29b may be extended upward so as to be inclined with respect to the upper surface of the substrate 11, and may not be perpendicular to the upper surface of the substrate 11.

What is claimed is:

1. A semiconductor device comprising:
a first connection target and a second connection target arranged on one surface of a substrate;
a first lead wire connected to the first connection target;
a second lead wire connected to the second connection target; and
a sealing resin that seals the first connection target, the second connection target, the first lead wire, and the second lead wire, wherein
the first lead wire includes
a first connection portion connected to the first connection target,
a first top portion exposed from the sealing resin, and
a first standing portion inclined with respect to the one surface and connecting the first connection portion and the first top portion,
the second lead wire includes
a second connection portion connected to the second connection target,
a second top portion exposed from the sealing resin, and
a second standing portion inclined with respect to the one surface and connecting the second connection portion and the second top portion, and
the first top portion and the second top portion are disposed to face each other.

2. The semiconductor device according to claim 1, wherein the first top portion and the second top portion face each other across a recess formed in the sealing resin.

3. The semiconductor device according to claim 2, wherein an end surface of the first top portion and an end surface of the second top portion are exposed from the sealing resin in the recess.

4. The semiconductor device according to claim 2, further comprising an embedded resin embedding the recess.

5. The semiconductor device according to claim 1, wherein
the first top portion has a tapered shape in which a thickness decreases from a part connected to the first standing portion toward an end part facing the second top portion, and
the second top portion has a tapered shape in which a thickness decreases from a part connected to the second standing portion toward an end part facing the first top portion.

6. A method of manufacturing a semiconductor device comprising:
disposing a plurality of connection targets on one surface of a substrate;
forming a bridge wiring having a shape for bridging the plurality of connection targets;
sealing the connection targets and the bridge wiring with a sealing resin;
exposing a part of the bridge wiring from a surface of the sealing resin; and
dividing an exposed part of the bridge wiring.

7. The method of manufacturing according to claim 6, wherein
the dividing includes forming a recess in a surface of the sealing resin so as to insulate the plurality of connection targets by removing a portion of the exposed part of the bridge wiring.

8. The method of manufacturing according to claim 7, further comprising:
forming a hole in a portion of the bridge wiring that is exposed from the sealing resin, wherein
the dividing includes removing a portion of the bridge wiring in which the hole is formed.

9. The method of manufacturing according to claim 6, wherein
the bridge wiring includes
a plurality of connection portions connected to a plurality of connection targets,
a top portion disposed opposite to the connection target with respect to the connection portion, and
a plurality of standing portions inclined with respect to the one surface and connecting the connection portion and the top portion,
the top portion has a thickness decreasing from a part connected to the standing portion toward a central portion,
the sealing includes disposing the sealing resin so that the connection portion, the standing portion, and at least a part of the top portion are sealed, and
the dividing includes removing a part of the top portion having a reduced thickness so as to divide the top portion into a plurality of units.
